(19) United States
(12) Patent Application Publication
(10) Pub. No.: US 2001/0045632 A1
(43) Pub. Date: Nov. 29, 2001

(54) SEMICONDUCTOR CHIP PACKAGE AND FABRICATION METHOD THEREFOR

(75) Inventor: DONG-YOU KIM, CHEONGJU (KR)

Correspondence Address: FLESHNER & KIM, PO BOX 221200, CHANTILLY, VA, 201531200

(73) Assignee: Hyundai Electronics Industries Co., Ltd.

(21) Appl. No.: 09/198,270

(22) Filed: Nov. 24, 1998

(30) Foreign Application Priority Data
Jun. 23, 1998 (KR) 23691/1998

(51) Int. Cl. H01L 23/02

(52) U.S. Cl. 257/678

(57) ABSTRACT

A semiconductor chip package and a fabrication method therefor are disclosed. The semiconductor chip package includes a semiconductor chip having a plurality of pads, a passivation film formed on the semiconductor chip and opened in the pads, a metallic film first pattern formed on the upper surfaces of the pads, a metallic film second pattern extended from a corresponding one of the metallic film first patterns formed on one pad among the pads to the passivation film and having a predetermined size which is two times compared to the area of one of the pads, and a plurality of leads formed on the metallic film first pattern.

### BACKGROUND OF THE INVENTION

1. Field of the Invention

The present invention relates to a semiconductor chip package and a fabrication method therefor, and in particular to a semiconductor chip package and a fabrication method therefor which are capable of improving a thermal emission characteristic and decreasing noise occurring in signals.

2. Description of the Background Art

Recently, as a system apparatus has a small-sized, thin type, and light weight feature, a semiconductor chip package is fabricated to have the same feature as the system apparatus. In addition, the system apparatus has a high operational performance, a multipin structure semiconductor package is needed.

A known semiconductor chip package having a small-sized, thin type and light weight feature and a multipin structure is disclosed in U.S. Pat. No. 5,467,211 with a title of “μ-spring package”.

FIG. 1 illustrates a known semiconductor chip which is not packaged. A plurality of pads 11 are spatially arranged at both edge portions on an upper surface of a semiconductor chip 10. The pads 11 have a similar size. The pads 11 are not formed at a center portion of the upper surface of the semiconductor chip 10. A passivation layer 12 is formed on the entire upper surface of the semiconductor chip 10 except for the pads 11. In the known semiconductor chip package which will be explained later, a plurality of leads are bonded to the pads 11 of the semiconductor chip 10 for thereby forming a semiconductor chip package. This semiconductor chip package is called as a bare chip. In addition, since the sizes of the semiconductor chip package and the semiconductor chip are identical, it is called as a chip size package (CSP).

FIG. 2 is a cross-sectional view taken along line II-II of FIG. 1. As shown therein, a finished semiconductor chip package is fabricated by bonding the leads 13 to the pads 11 of FIG. 1. Namely, one end of each of the leads 13 is bonded to a corresponding one of the pads 11 of the semiconductor chip 10, and another end of each of the same is bonded to a printed circuit board (PCB) 14.

The description of the reference numerals of FIG. 2 which are the same as in FIG. 1 will be omitted.

Next, the known semiconductor chip package fabrication method will be explained with reference to FIGS. 3A through 3E.

First, FIG. 3A illustrates a semiconductor chip which is not packaged. Namely, a plurality of pads 11 are formed at edge portions on an upper surface of the semiconductor chip 10. A passivation film 12 covers the upper surface of the semiconductor chip 10 except for the pads 11. The passivation film is made of a Boron Phosphorous silicate Glass (BPSG) or a polyimide. The semiconductor chip as shown in FIG. 3A is rinsed before the semiconductor chip is packaged.

Next, as shown in FIG. 3B, a tungsten titanium (TiW) film 31 and Au film 32 are sequentially formed on the entire structure shown in FIG. 3A by a sputtering method in the manner shown in FIG. 3B.

A photoresist (not shown) is formed on the entire structure of FIG. 3B, and then the photoresist film is patterned as shown in FIG. 3C, and then a photoresist pattern 33a having an opening portion 33 is formed in such a manner that the surface of the Au film 32 corresponding to the pads 11 are exposed.

As shown in FIG. 3D, a wire made of Au is bonded to the surface of the exposed Au film 32 through the opening portion 33. Here, the wire portion 34 is shaped as shown in FIG. 3D.

As shown in FIG. 3E, the surface of the wire portion 34 is coated with a nickel film 35 and a Au film 36. Since the wire portion 34 is made of a flexible material having a relatively row mechanical strength, the wire portion 34 is easily deformed. Therefore, in order to overcome the above-described problems, the surface of the wire portion 34 is coated with a nickel having a high elastic force and strength. In addition, the surface of the nickel-coated surface is coated with Au for the reason that the nickel component is easily oxidized in the air.

As shown in FIG. 3F, the photoresist film pattern 33a is removed, and another photoresist film 37 is formed on the entire structure as shown in FIG. 3E.

Next, as shown in FIG. 3G, the photoresist film 37 is patterned so that the portion on which the wire portion 34 is formed is left for thereby forming a photoresist pattern 37a. The Au film 32 and the tungsten film 31 formed on the upper surface of the semiconductor chip 10 are sequentially etched using the photoresist film pattern 37a as a mask. Thereafter, the photoresist film pattern 37a is removed, so that the semiconductor chip package having the leads 13 as shown in FIG. 3H is fabricated.

As described above, in the known semiconductor chip package, since the size of the semiconductor chip package is very small for a chip size package, and the encapsulation process including a molding process is omitted, it is possible to effectively implement a compact system, and the fabrication cost for the package is low. However, there are the following problems.

As a multipin structure is used, the distance between leads is shorter, and much heat is generated during operation of the semiconductor chip. However, in the above-described known semiconductor chip, a thermal emission is not well implemented. In addition, a predetermined noise occurs in signal due to a narrower lead pitch, so that the semiconductor chip is not properly operated.

### SUMMARY OF THE INVENTION

Accordingly, it is an object of the present invention to provide a semiconductor chip package and a fabrication method therefor which overcome the aforementioned problems encountered in the background art.

It is another object of the present invention to provide a semiconductor chip package and a fabrication method therefor which are capable of improving a thermal emission characteristic and decreasing noise occurring in signals.

To achieve the above objects, there is provided a semiconductor chip package which includes a semiconductor chip having a plurality of pads, a passivation film formed on the semiconductor chip and opened in the pads, a metallic film first pattern formed on the upper surfaces of the pads, a metallic film second pattern extended from a corresponding one of the metallic film first patterns formed on one pad among the pads to the passivation film and having a predetermined size which is two times compared to the area of one of the pads, and a plurality of leads formed on the metallic film first pattern.

To achieve the above objects, there is provided a semiconductor chip package fabrication method which includes the steps of forming a passivation film on the semiconductor chip having a plurality of pads so that the upper surfaces of the pads are exposed, forming the pads on the metallic film first pattern, forming a metallic film second pattern on the passivation film for being connected with at least one of the metallic film first pattern, and forming a lead on the metallic film first pattern.

Additional advantages, objects and features of the invention will become more apparent from the description which follows.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a plan view illustrating an upper surface of a known semiconductor chip package;

FIG. 2 is a cross-sectional view taken along line 11-11 of the semiconductor chip package of FIG. 1;

FIGS. 3A through 3H are cross-sectional views illustrating a semiconductor chip package for explaining a known semiconductor chip fabrication method;

FIG. 4 is a plan view illustrating an upper surface of a semiconductor chip package according to the present invention; and

FIGS. 5A through 5G are cross-sectional views illustrating a semiconductor chip package for explaining a semiconductor chip package fabrication method according to the present invention.

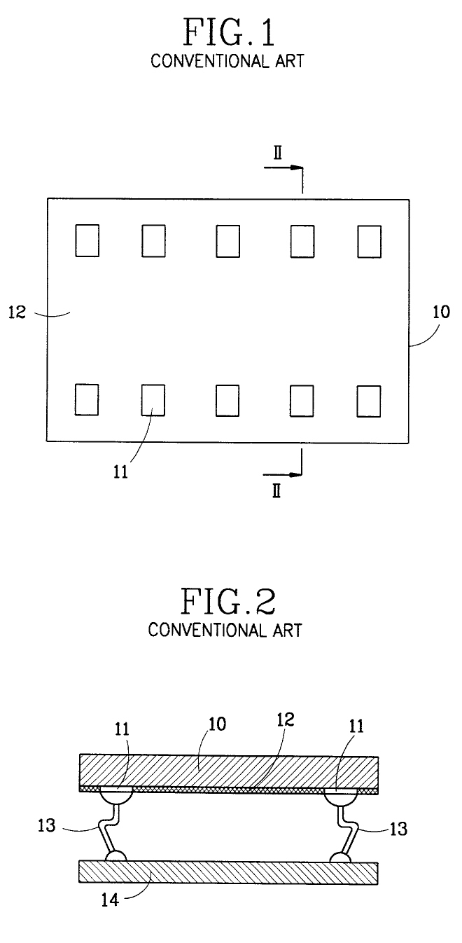

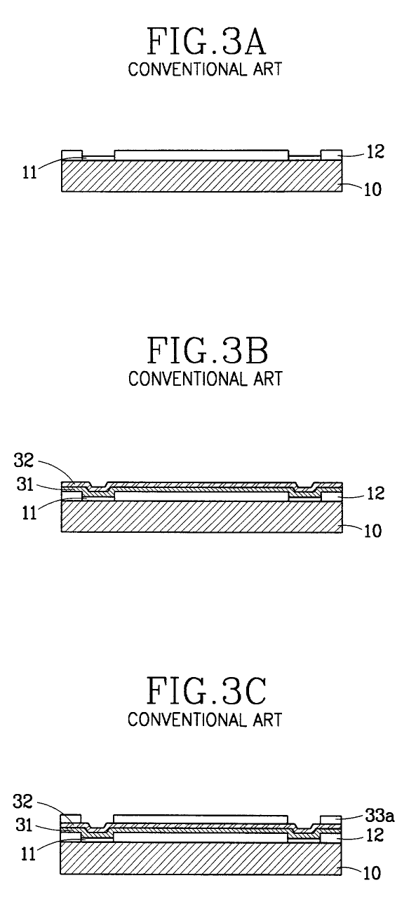

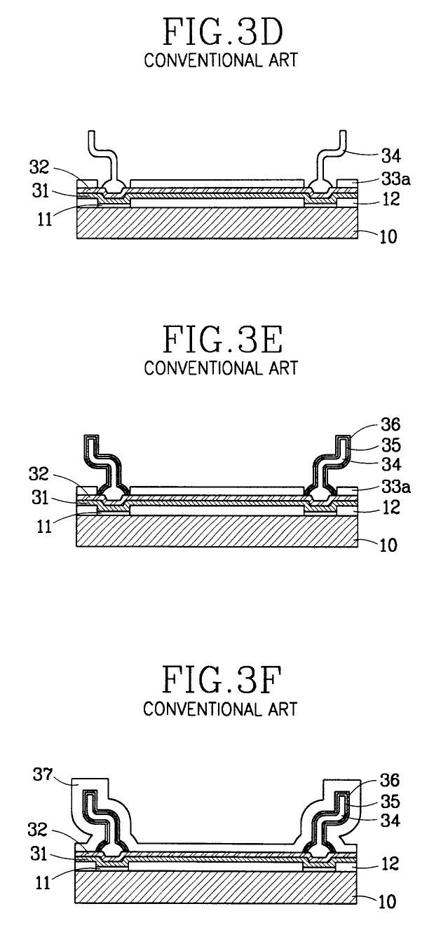

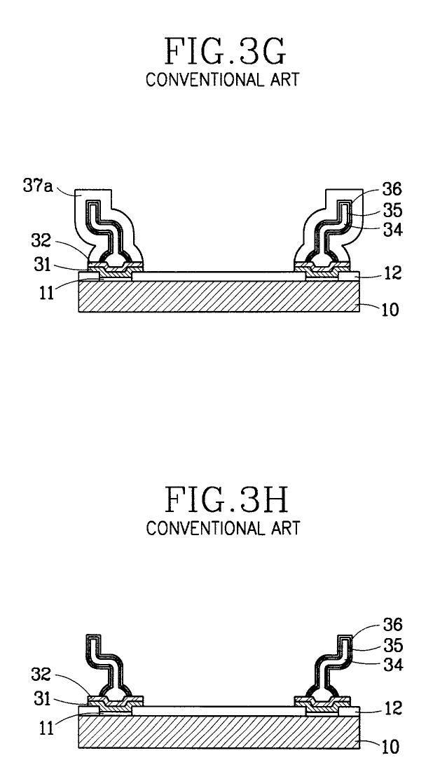

### DETAILED DESCRIPTION OF THE PREFERRED EMBODIMENTS

The construction of the semiconductor chip package according to the present invention will be explained with reference to the accompanying drawings.

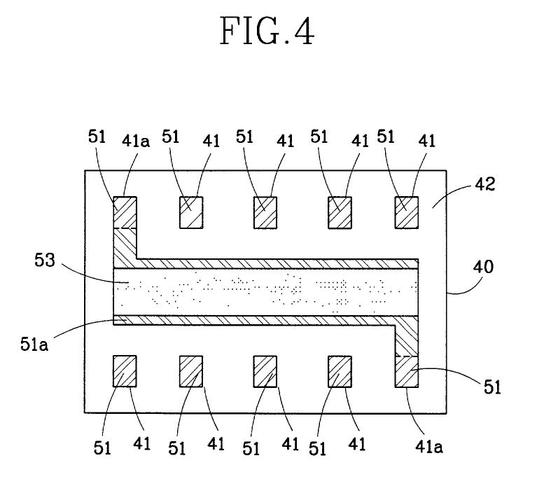

FIG. 4 is a plan view illustrating a semiconductor chip package which is not packaged according to the present invention.

A plurality of pads 41, 41a are spatially formed at edge portions of an upper surface of a semiconductor chip 40. A passivation film 42 is formed on an upper surface of the semiconductor chip 40 except for the portions on which the pads 41, 41a are formed. A metallic film first pattern 51 is formed on the pads 41, 41a, respectively. A metallic film second pattern 51a is formed on an upper surface of the passivation film 42. The metallic film second pattern 51a is extended from the metallic film first pattern 51 on at least one pad 41a. Therefore, the metallic film second pattern 51a is electrically connected with at least one pad 41a among the plurality of pads. The pad 41a connected with the metallic film second pattern 51a may be a pad to which a ground voltage is supplied or an electric power voltage is supplied thereto. In addition, when more than one pad 41a is formed on the semiconductor chip for receiving and outputting the identical signals, the above-described pads 41a may be connected with the metallic film second pattern 51a. As shown in FIG. 4, preferably, two pads 41a to which a ground voltage is applied are formed. Two ground voltage pads 41a are connected with the metallic film second pattern 51a.

In addition, the metallic film second pattern 51a is spaced apart from the metallic film first pattern 51.

A metallic plate 53 is formed on the metallic film second pattern 51a.

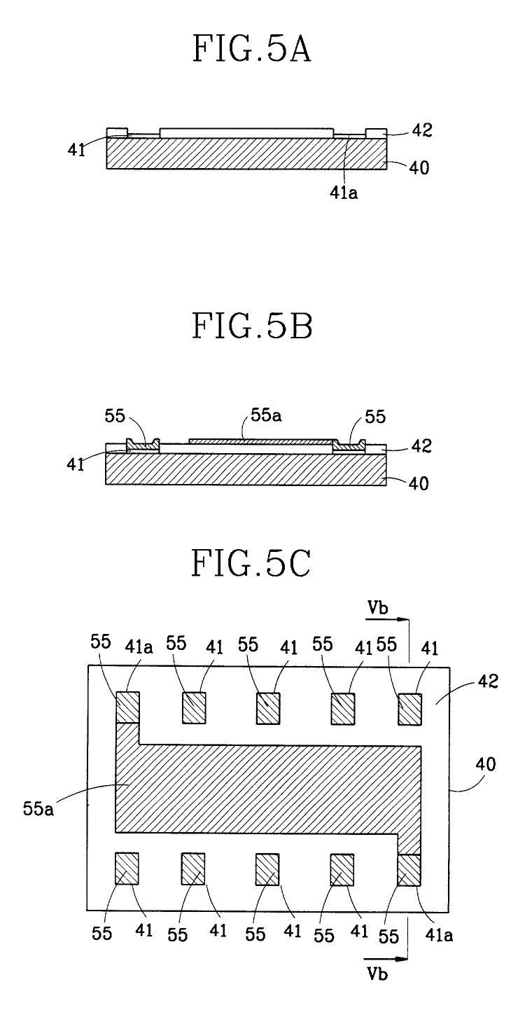

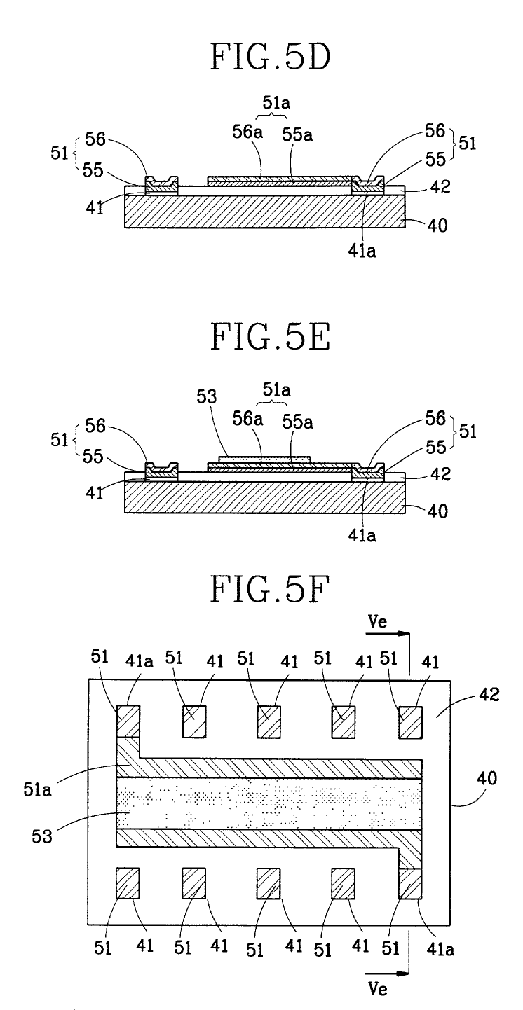

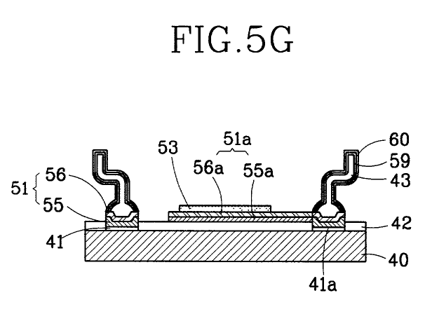

As not shown in FIG. 4 but in FIG. 5G, the leads 53a are formed on the metallic film first pattern 51, and the leads 54 include a Au-coated wire portion 43, a nickel film 59 coated on an outer surface of the wire portion 43, and a Au film 60.

The principle that the semiconductor chip package according to the present invention emits heat and decreases noise in signals will be explained.

The metallic film second pattern 51 a is connected with the ground voltage pad 41a or the electric power voltage pad. Since the metallic film second pattern 51 is formed on the upper surface of the passivation film 42, namely, the entire surface except for the pad portions of the semiconductor package, a heat generated during operation of the semiconductor chip is transferred to the metallic film second pattern 51a along the pads 41a, and then the thusly transferred heat is effectively emitted to the outside through the metallic plate 53 of the metallic film second pattern 51a. Therefore, as the widths of the metallic film second pattern 51a and the metallic plate 53 are increased, it is possible to implement a desired heat transfer. More preferably, the widths of the metallic film second pattern 51a and the metallic plate 53 are two times the area of the pads 41 and 41a.

The fabrication method for a semiconductor chip package according to the present invention will be explained.

The semiconductor chip 40 as shown in FIG. 5A is prepared. A plurality of pads 41 and 41a are formed at edge portions of an upper surface of the semiconductor chip 40. The passivation film 42 covers the semiconductor chip 40 and the pad 41, and then the passivation film 42 is patterned for thereby forming an opening portion in such a manner that the pads 41 and 41a are exposed.

Next, a tungsten titanium film (not shown) is formed on the entire structure as shown in FIG. 5A and is patterned for thereby forming the structure of FIG. 5B. Namely, the tungsten titanium pattern 55 is formed on the pads 41 and 41a formed on the edge portions of the semiconductor chip 40. The tungsten titanium pattern 55a is formed on the upper surface of the passivation film 42. The tungsten titanium pattern 55a is extended from the tungsten titanium film pattern 55 formed on at least one pad 41a, namely, is connected with one pad 41a. The tungsten titanium pattern 55a is spaced apart from the tungsten titanium film pattern 55 for thereby implementing an electrical isolation therebetween.

Next, the Au film patterns 56 and 56a are formed on the upper surfaces of the tungsten titanium patterns 55 and 55a for thereby forming the structure as shown in FIG. 5D.

The tungsten titanium patterns 55 and 55a and the Au patterns 56 and 56a as shown in FIG. 5D are formed by sequentially forming a tungsten titanium (not shown) and a Au film (not shown) on the structure of FIG. 5A and then concurrently etching the tungsten titanium film and the Au film. The structure of the tungsten titanium pattern 55 and the Au film pattern 56 formed on the pads 41 and 41 a is called a metallic film first pattern 51. In addition, the tungsten titanium pattern 55a and the Au film pattern 56a formed thereon are called as a metallic film second pattern 51a.

Next, as shown in FIG. 5E, a metallic plate 53 formed of a nickel film 57 and a Au film 58 is formed on the metallic film second pattern 51 a. At this time, the nickel film 57 and the Au film 58 may be formed by a known thin film formation method such as a sputtering deposition method and a lithography method. In addition, a nickel plate or a Au plate may be independently manufactured by a thermal pressing method for thereby bonding the same. FIG. 5F is a plan view illustrating the structure of FIG. 5E.

A Au wire is attached to the first metallic film pattern 51 formed on the pads 41 and 41a and then is bent for thereby forming a Au wire 43. Next, A nickel film 59 is coated on the outer surface of the Au wire portion 43 for increasing a mechanical strength of the lead, and then a Au film 60 is coated on the outer surface of the nickel film 59 for preventing oxidation of the nickel film 59 for thereby forming the lead 54. Therefore, the semiconductor chip package fabrication method according to the present invention is implemented through the processes shown in FIGS. 5A through 5G.

As described above, in the semiconductor chip package according to the present invention, at least one pad among the bending pads is connected with the semiconductor chip, and the metallic pattern electrically isolated from the remaining pads is formed on the passivation film of the semiconductor chip, so that the heat generated in the semiconductor chip is effectively emitted to the outside for thereby decreasing noise in the signals (leads). Therefore, it is possible to implement a reliable operation of the semiconductor chip.

Although the preferred embodiment of the present invention have been disclosed for illustrative purposes, those skilled in the art will appreciate that various modifications, additions and substitutions are possible, without departing from the scope and spirit of the invention as recited in the accompanying claims.

What is claimed is:

1. A semiconductor chip package, comprising:
a semiconductor chip having a plurality of pads;
a passivation film formed on the semiconductor chip and opened in the pads;
a metallic film first pattern formed on the upper surfaces of the pads;
a metallic film second pattern extended from a corresponding one of the metallic film first patterns formed on one pad among the pads to the passivation film and having a predetermined size which is two times compared to the area of one of the pads; and
a plurality of leads formed on the metallic film first pattern.

2. The package of claim 1, wherein a metallic plate is formed on the metallic film second pattern.

3. The package of claim 1, wherein said metallic first pattern or said metallic film second pattern is formed of a stacked film formed of a tungsten titanium film and a Au film.

4. The package of claim 2, wherein said metallic plate is formed of a stacked film formed of a nickel film and a Au film.

5. The package of claim 1, wherein said lead is formed of a nickel film and a Au film coated on an outer surface of the metallic wire.

6. The package of claim 1, wherein at least one pad electrically connected with the metallic film second pattern is a ground voltage pad.

7. The package of claim 1, wherein at least one pad electrically connected with the metallic film second pattern is an electrical power pad.

8. The package of claim 1, wherein the number of pads electrically connected with the metallic film second pattern is two, and the pads are formed to input/output the identical signals into/from the semiconductor chip.

9. The package of claim 8, wherein said pads are a ground voltage pad.

10. A semiconductor chip package fabrication method, comprising the steps of:
forming a passivation film on the semiconductor chip having a plurality of pads so that the upper surfaces of the pads are exposed;
forming the pads on the metallic film first pattern;
forming a metallic film second pattern on the passivation film for being connected with at least one of the metallic film first pattern; and
forming a lead on the metallic film first pattern.

11. The method of claim 10, wherein after forming the metallic film second pattern a metallic plate is formed on the metallic film second pattern.

12. The method of claim 10, wherein said metallic film first pattern formation step and said metallic film second pattern formation step are concurrently performed.

13. The method of claim 10, wherein said metallic film first pattern and said metallic film second pattern are made of TiW and Au.

14. The method of claim 10, wherein said metallic plate formation step includes the steps of:
forming a metallic thin film on the metallic film second pattern; and
patterning the metallic thin film.

15. The method of claim 10, wherein said metallic plate formation step is directed to sequentially attaching a nickel plate and a Au plate on the metallic film second pattern.

16. The method of claim 10, wherein said step for forming a lead on the metallic film first pattern includes the steps of:
attaching a metallic wire portion on the metallic film first pattern; and
sequentially coating a nickel and Au on an outer surface of the metallic wire portion.
